(19) United States
(12) Patent Application Publication
(10) Pub. No.: US 2005/0068833 A1
(43) Pub. Date: Mar. 31, 2005

(54) Input/output line sense amplifiers and/or input/output line drivers in semiconductor memory devices and methods of operating such devices

(76) Inventor: Jung-hwan Choi, Gyeonggi-do (KR)

Correspondence Address: Robert N. Crouse;Myers Bigel Sibley & Sajovec, Post Office Box 37428, Raleigh, NC, 27627, US

(21) Appl. No.: 10/948,498

(22) Filed: Sep. 23, 2004

(30) Foreign Application Priority Data
Sep. 30, 2003 (KR) 10-2003-0067912

(51) Int. Cl. G11C 7/00

(52) U.S. Cl. 365/222

(57) ABSTRACT

Semiconductor memory devices and methods of operating semiconductor memory devices that sequentially enable sense amplifiers and/or line drivers for input/output lines of a memory cell array are provided. The data read from the memory cell array and provided to the memory cell array may be provided by a pipeline circuit that may include a multiplexer.

### CLAIM OF PRIORITY

This application is related to and claim priority from Korean Patent Application No. 2003-67912 filed on Sep. 30, 2003 in the Korean Intellectual Property Office, the disclosure of which is incorporated herein in its entirety by reference.

### FIELD OF THE INVENTION

The present invention relates to semiconductor memory devices, and more particularly, to input/output (I/O) line sense amplifiers and/or I/O line drivers of semiconductor memory devices and their operation.

### BACKGROUND

As data input/output (I/O) speeds of dynamic random access memories (DRAMs) have increased, the data prefetch mode in which the DRAM core operates has typically changed from a 2-bit data prefetch mode to a 4, 8, or 16 bit data prefetch mode. That is, several bits of data are output from the DRAM core in parallel and then output from an output buffer in series. For input of data to the DRAM core, the data is input in series to an input buffer and stored in the DRAM core in parallel.

The increase in the number of bits of prefetch data typically results in an increase in the number of I/O line sense amplifiers that operate simultaneously for the output of data and an increase in number of I/O line drivers that operate simultaneously for the input of data, thus increasing peak operating current and/or power consumption. An increase in the peak operating current and/or power consumption may produce noise that may deteriorate operating characteristics of the DRAM.

FIG. 1 illustrates a structure of a conventional DRAM performing a method of controlling I/O line sense amplifiers. FIG. 2 illustrates a conventional DRAM performing a method of controlling I/O line drivers. For convenience, only 8-bit data prefetch will be described.

Referring to FIG. 1, for output of data, 8-bit data read from a DRAM core (memory cell array) 11 is input to eight I/O line sense amplifiers 121 through 128 via eight I/O lines IO1 through IO8 in parallel, and the input 8-bit data is amplified by the I/O line sense amplifiers 121 through 128. In this case, all of the eight I/O line sense amplifiers 121 through 128 are enabled simultaneously in response to a sense amplification enable signal SAEN. A pipeline circuit 13 receives in parallel the 8-bit data amplified by the I/O line sense amplifiers 121 through 128 and outputs the 8-bit data via an I/O pin DQ in series.

Referring to FIG. 2, for the input of data to the DRAM, 8-bit data is input to and stored in a pipeline circuit 23 in series via an I/O pin DQ. All of the 8-bit data stored in the pipeline circuit 23 is output in parallel. Eight I/O line drivers 221 through 228 receive the 8-bit data stored in the pipeline circuit 23 in parallel and transmit the 8-bit data to a DRAM core (memory cell array) 21 via eight I/O lines IO1 through IO8. In this case, all eight I/O line drivers 221 through 228 are simultaneously enabled in response to a driver enable signal DRVEN.

However, as described above, an increase in the number of bits of prefetch data results in an increase in a number of I/O line sense amplifiers that operate simultaneously for output of data and an increase in a number of I/O line drivers that operate simultaneously for input of data. In this case, peak operating current and/or power consumption may increase, which may produce noise. The occurrence of noise may deteriorate the operating characteristics of the DRAM.

### SUMMARY

Some embodiments of the present invention provide a semiconductor memory device that includes a memory cell array, a plurality of input/output line sense amplifiers each configured to receive in parallel a bit of data read from the memory cell array via a corresponding input/output line and amplify the received bit data and a pipeline circuit configured to receive the plurality of bits of data amplified by the input/output line sense amplifiers and outputs the amplified bits of data via an input/output pin in series. The input/output line sense amplifiers are divided into a plurality of groups, at least one of the groups having a plurality of input/output sense amplifiers, and the groups are sequentially enabled with each subsequent group being enabled an interval of time after a previous group.

In further embodiments of the present invention, the pipeline circuit includes an N:1 multiplexer where N is the number of bits of data. Furthermore, the plurality of input/output line sense amplifiers may be configured such that predetermined interval of time between respective groups is fixed.

In still further embodiments of the present invention, a semiconductor memory device includes a memory cell array, a pipeline circuit configured to receive in series a plurality of bits of data input via an input/output pin and stores the plurality of bits of data and a plurality of input/output line drivers each configured to receive a bit of data stored in the pipeline circuit and transmit the received bit of data to a memory cell array via a corresponding one of a plurality of input/output lines. The plurality of input/output line drivers are divided into a plurality of groups and the groups are configured to be sequentially enabled with an interval of time between enabling of subsequent groups.

In additional embodiments of the present invention, the pipeline circuit includes an N:1 multiplexer where N is the number of bits. The semiconductor memory device may also include a plurality of input/output line sense amplifiers each configured to receive in parallel a bit of data read from the memory cell array via a corresponding input/output line and amplify the received bit data. The plurality of input/output line sense amplifiers are divided into a plurality of groups and the groups are configured to be sequentially enabled with an interval of time between enabling of subsequent groups.

Yet other embodiments of the present invention provide for controlling a plurality of input/output line sense amplifiers in a semiconductor memory device that receive data in parallel from a memory cell array of the semiconductor memory device by enabling a first subset of the input/output line sense amplifiers that include a plurality of input/output line sense amplifiers when the input/output line sense amplifiers receive the data from the memory cell array and enabling a second subset of input/output line sense amplifiers, different from the first subset, after an interval of time. The output of the input/output line sense amplifiers is provided to a pipeline circuit that serially outputs the data received in parallel. The second subset of input/output line sense amplifiers may be the remaining input/output line sense amplifiers. Furthermore, the pipeline circuit may include a multiplexer.

Some embodiments of the present invention provide for controlling input/output line drivers in a semiconductor memory device that receive data in parallel from a pipeline circuit and provide the received data to a memory cell array of the semiconductor memory device by enabling a first subset of the input/output line drivers when the input/output line drivers receive the data from the pipeline circuit and enabling a second subset of input/output line drivers, different from the first subset, after an interval of time when the input/output line drivers receive the data from the pipeline circuit. The second subset of input/output line drivers may be the remaining input/output line drivers. The pipeline circuit may include a multiplexer.

Still further embodiments of the present invention provide for controlling input/output lines in a semiconductor memory device that receive data in parallel from a pipeline circuit and provide the received data to a memory cell array of the semiconductor memory device and that receive data in parallel from the memory cell array and provide the received data from the memory cell array to the pipeline circuit by enabling a first subset of input/output line drivers associated with the input/output lines when the input/output line drivers receive the data from the pipeline circuit, enabling a second subset of input/output line drivers, different from the first subset, after an interval of time when the input/output line drivers receive the data from the pipeline circuit, enabling a first subset of input/output sense amplifiers associated with the input/output lines when the input/output line sense amplifiers receive the data from the memory cell array and enabling a second subset of input/output sense amplifiers, different from the first subset, after an interval of time when the input/output line sense amplifiers receive the data from the memory cell array.

In some embodiments, the pipeline circuit includes a multiplexer. Furthermore, the second subset of input/output line drivers may be the remaining input/output line drivers. The second subset of input/output line sense amplifiers may be the remaining input/output line sense amplifiers.

### BRIEF DESCRIPTION OF THE DRAWINGS

FIG. 1 is a block diagram illustrating a conventional DRAM and a method of controlling input/output (I/O) line sense amplifiers of a conventional DRAM.

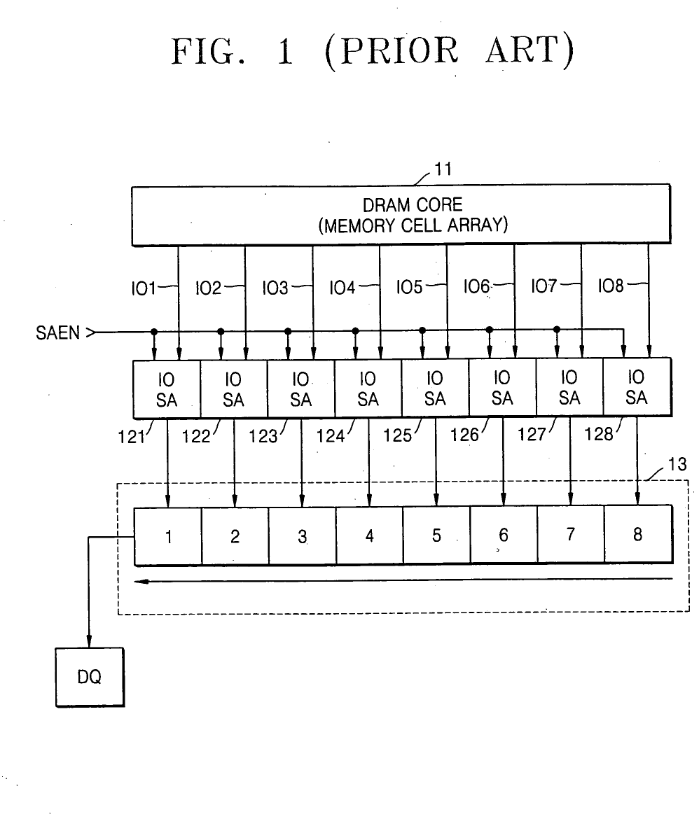

FIG. 2 is a block diagram illustrating a conventional DRAM and a method of controlling I/O line drivers of a conventional DRAM.

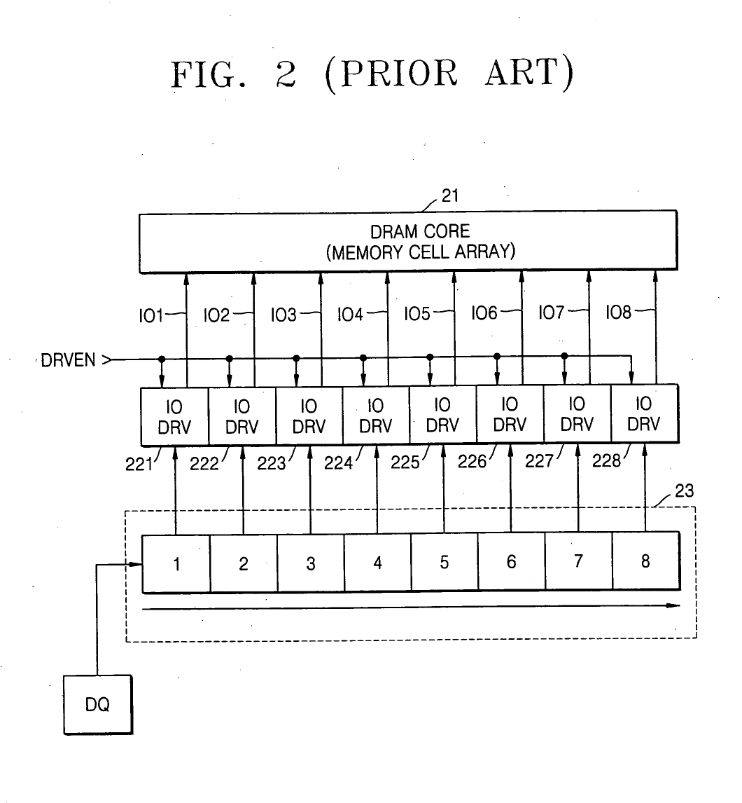

FIG. 3 is a block diagram illustrating a structure of a DRAM according to some embodiments of the present invention and methods of controlling I/O line sense amplifiers according to some embodiments of the present invention.

FIG. 4 is a block diagram illustrating a structure of a DRAM according to some embodiments of the present invention and methods of controlling I/O line drivers according to some embodiments of the present invention.

### DETAILED DESCRIPTION OF THE INVENTION

The present invention will now be described more fully with reference to the accompanying drawings, in which embodiments of the invention are shown. This invention may, however, be embodied in different forms and should not be construed as being limited to the embodiments set forth herein. Rather, these embodiments are provided so that this disclosure will be thorough and complete, and will fully convey the scope of the invention to those skilled in the art. Like numbers refer to like elements. As used herein the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

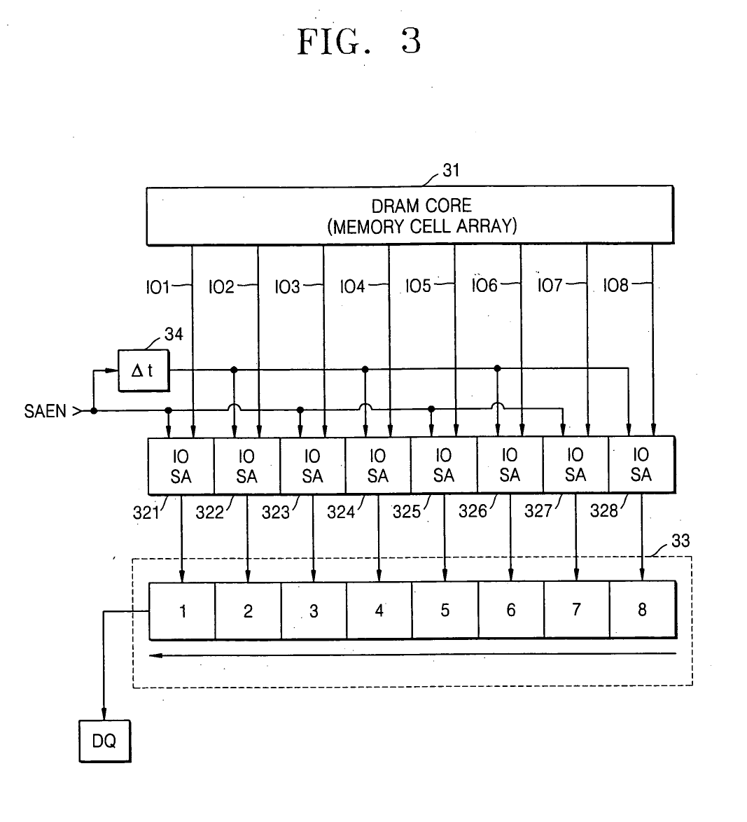

FIG. 3 illustrates a portion of a Dynamic Random Access Memory (DRAM) according to some embodiments of the present invention and methods of controlling input/output (I/O) line sense amplifiers according to some embodiments of the present invention. For convenience, embodiments of the present invention will be described with reference to 8-bit data prefetch, however, other numbers of bits may be provided.

The DRAM of FIG. 3 includes a DRAM core (memory cell array) 31, eight I/O line sense amplifiers 321 through 328, a pipeline circuit 33, and a delay circuit 34. During output of data from the DRAM, sense amplification enable signal SAEN is delayed by the delay circuit 34 for a predetermined time. The sense amplifiers 321, 323, 325, and 327, belonging to a first group, are enabled in response to the sense amplification enable signal SAEN. The remaining sense amplifiers 322, 324, 326, and 328 belong to a second group and are enabled in response to a signal output from the delayer circuit 34 obtained by delaying the sense amplification enable signal SAEN for the predetermined time. In other words, the I/O line sense amplifiers 321 through 328 are divided into two groups, and the I/O line sense amplifiers 321, 323, 325, and 327 belonging to the first group and the I/O sense amplifiers 322, 324, 326, and 328 belonging to the second group are sequentially enabled with a predetermined interval of time interposed between the enabling of the two groups. In some embodiments, the sequential relationship between the two groups remains the same between successive prefetch operations.

More specifically, the sense amplifiers 321, 323, 325, and 327 of the first group receive and amplify 4 bits of 8-bit data read from the memory cell array 31 input via four I/O lines IO1, IO3, IO5, and IO7. After the interval of time, the sense amplifiers 322, 324, 326, and 328 of the second group receive and amplify the remaining 4 bits of the 8-bit data input via the other four I/O lines IO2, IO4, IO6, and IO8.

The pipeline circuit 33 receives all of the 8-bit data amplified from the eight I/O line sense amplifiers 321 through 328 and outputs the 8-bit data via an I/O pin DQ in series. FIG. 3 illustrates a case where the I/O line sense amplifiers 321 through 328 are divided into two groups and the two groups are sequentially enabled with a predetermined interval of time interposed between the enabling of the two groups. However, the present invention is not limited to the above description. For instance, the I/O line sense amplifiers 321 through 328 may be divided into three or more groups and these groups are sequentially enabled with a predetermined interval of time interposed between the enabling of the two groups.

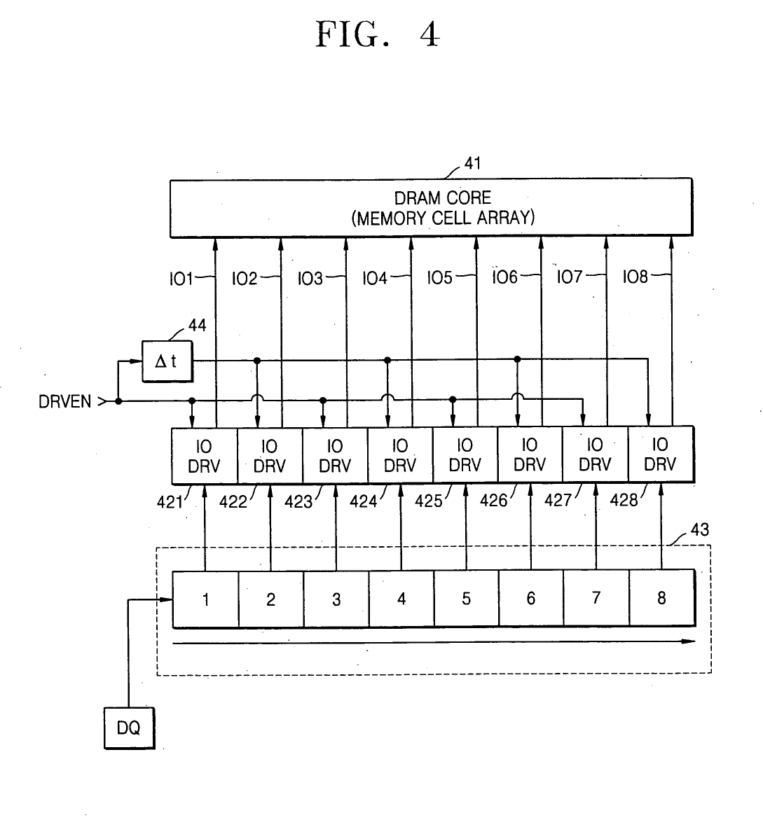

FIG. 4 illustrates structures of a Dynamic Random Access Memory (DRAM) according to further embodiments of the present invention and methods of controlling I/O line drivers according to further embodiments of the present invention. The DRAM of FIG. 4 includes a DRAM core (memory cell array) 41, eight I/O line drivers 421 through 428, a pipeline circuit 43, and a delay circuit 44.

During input of data to the DRAM, the pipeline circuit 43 receives and stores 8-bit data input via an I/O pin DQ in series. A driver enable signal DRVEN is delayed by the delayer circuit 44 for a predetermined time. The line drivers 421, 423, 425, and 427 of a first group are enabled in response to the driver enable signal DRVEN, and then, the remaining line drivers 422, 424, 426, and 428 of a second group are enabled in response to a signal output from the delayer circuit 44 and obtained by delaying the driver enable signal DRVEN for the predetermined time. In other words, the I/O line drivers 421 through 428 are divided into two groups, and the I/O line drivers 421, 423, 425, and 427 belonging to the first group and the I/O line drivers 422, 424, 426, and 428 belonging to the second group are sequentially enabled with a predetermined interval of time interposed between the enabling of the two groups. In some embodiments, the sequential relationship between the two groups remains the same between successive storage operations.

Accordingly, the drivers 421, 423, 425, and 427 of the first group receive 4 bits of 8-bit data stored in the pipeline circuit 43 and send the 4 bits of data to the memory cell array 41 via four I/O lines IO1, IO3, IO5, and IO7. After the predetermined interval of time, the drivers 422, 424, 426, and 428 of the second group receive the remaining 4 bits of the 8-bit data and send the 4 bits of data to the memory cell array 41 via the other four I/O lines IO2, IO4, IO6, and IO8.

The pipeline circuit 43 includes an 8:1 multiplexer. FIG. 4 illustrates a case where the I/O line drivers 421 through 428 are divided into two groups and the two groups are sequentially enabled with a predetermined interval of time interposed between the enabling of the two groups. However, the present invention is not limited to the above description. For instance, the I/O line drivers 421 through 428 may be divided into three or more groups and these groups are sequentially enabled with a predetermined interval of time before the enabling of each subsequent group.

While structures of DRAMs and methods of controlling I/O line sense amplifiers and structures of DRAMs and methods of controlling I/O line drivers according to embodiments of the present invention have been described individually, these structures and/or methods may be combined to provide structures and/or methods of controlling I/O line sense amplifiers and I/O line drivers such that the I/O line sense amplifiers operate as specified by the methods of controlling I/O line sense amplifiers according to the present invention and the I/O line drivers operate as specified by the methods of controlling I/O line drivers according to the present invention.

As described above, according to some embodiments of the present invention, while outputting data from a DRAM, I/O line sense amplifiers are divided into a plurality of groups, and these groups are sequentially enabled with a predetermined interval of time before each subsequent group is enabled. Also, when inputting data to the DRAM, I/O line drivers are divided into a plurality of groups, and these groups are sequentially enabled with a predetermined interval of time before each subsequent group is enabled. Accordingly, a number of I/O line sense amplifiers that operate simultaneously to output data and a number of I/O line drivers that operate simultaneously to input data may be reduced, thereby reducing peak current and/or power consumption. As a result, noise caused by an increase in power consumption may be reduced which may improve operating characteristics of DRAM.

While this invention has been particularly shown and described with reference to exemplary embodiments thereof, it will be understood by those skilled in the art that various changes in form and details may be made therein without departing from the spirit and scope of the invention as defined by the appended claims.

1. A semiconductor memory device comprising:
a memory cell array;
a plurality of input/output line sense amplifiers each configured to receive in parallel a bit of data read from the memory cell array via a corresponding input/output line and amplify the received bit data; and
a pipeline circuit configured to receive the plurality of bits of data amplified by the input/output line sense amplifiers and outputs the amplified bits of data via an input/output pin in series,
wherein the input/output line sense amplifiers are divided into a plurality of groups, at least one of the groups having a plurality of input/output sense amplifiers, and the groups are sequentially enabled with each subsequent group being enabled an interval of time after a previous group.

2. The semiconductor memory device of claim 1, wherein the pipeline circuit comprises an N:1 multiplexer where N is the number of bits of data.

3. The semiconductor memory device of claim 1, wherein the plurality of input/output line sense amplifiers are configured such that predetermined interval of time between respective groups is fixed.

4. A semiconductor memory device comprising:
a memory cell array;
a pipeline circuit configured to receive in series a plurality of bits of data input via an input/output pin and stores the plurality of bits of data; and
a plurality of input/output line drivers each configured to receive a bit of data stored in the pipeline circuit and transmit the received bit of data to a memory cell array via a corresponding one of a plurality of input/output lines, the plurality of input/output line drivers being divided into a plurality of groups and the groups being configured to be sequentially enabled with an interval of time between enabling of subsequent groups.

5. The semiconductor memory device of claim 3, wherein the pipeline circuit comprises an N:1 multiplexer where N is the number of bits.

6. The semiconductor memory device of claim 4, further comprising a plurality of input/output line sense amplifiers each configured to receive in parallel a bit of data read from the memory cell array via a corresponding input/output line and amplify the received bit data, the plurality of input/output line sense amplifiers being divided into a plurality of groups and the groups being configured to be sequentially enabled with an interval of time between enabling of subsequent groups.

7. A method of controlling a plurality of input/output line sense amplifiers in a semiconductor memory device that receive data in parallel from a memory cell array of the semiconductor memory device, the method comprising:
enabling a first subset of the input/output line sense amplifiers comprising a plurality of input/output line sense amplifiers when the input/output line sense amplifiers receive the data from the memory cell array;
enabling a second subset of input/output line sense amplifiers, different from the first subset, after an interval of time; and
providing the output of the input/output line sense amplifiers to a pipeline circuit that serially outputs the data received in parallel.

8. The method of claim 7, wherein the second subset of input/output line sense amplifiers comprises the remaining input/output line sense amplifiers.

9. The method of claim 7, wherein the pipeline circuit comprises a multiplexer.

10. A method of controlling input/output line drivers in a semiconductor memory device that receive data in parallel from a pipeline circuit and provide the received data to a memory cell array of the semiconductor memory device, the method comprising:
enabling a first subset of the input/output line drivers when the input/output line drivers receive the data from the pipeline circuit; and
enabling a second subset of input/output line drivers, different from the first subset, after an interval of time when the input/output line drivers receive the data from the pipeline circuit.

11. The method of claim 10, wherein the second subset of input/output line drivers comprises the remaining input/output line drivers.

12. The method of claim 10, wherein the pipeline circuit comprises a multiplexer.

13. A method of controlling input/output lines in a semiconductor memory device that receive data in parallel from a pipeline circuit and provide the received data to a memory cell array of the semiconductor memory device and that receive data in parallel from the memory cell array and provide the received data from the memory cell array to the pipeline circuit, the method comprising:
enabling a first subset of input/output line drivers associated with the input/output lines when the input/output line drivers receive the data from the pipeline circuit;
enabling a second subset of input/output line drivers, different from the first subset, after an interval of time when the input/output line drivers receive the data from the pipeline circuit;
enabling a first subset of input/output sense amplifiers associated with the input/output lines when the input/output line sense amplifiers receive the data from the memory cell array; and
enabling a second subset of input/output sense amplifiers, different from the first subset, after an interval of time when the input/output line sense amplifiers receive the data from the memory cell array.

14. The method of claim 13, wherein the pipeline circuit comprises a multiplexer.

15. The method of claim 13, wherein the second subset of input/output line drivers comprises the remaining input/output line drivers.

16. The method of claim 13, wherein the second subset of input/output line sense amplifiers comprises the remaining input/output line sense amplifiers.
